(19) United States
(12) Patent Application Publication
(10) Pub. No.: US 2013/0299091 A1
(43) Pub. Date: Nov. 14, 2013

(54) PLASMA PROCESSING APPARATUS

(71) Applicant: HITACHI HIGH-TECHNOLOGIES CORPORATION, Tokyo (JP)

(72) Inventors: Yusaku SAKKA, Kudamatsu-shi (JP); Ryoji NISHIO, Kudamatsu-shi (JP); Tadayoshi KAWAGUCHI, Kudamatsu-shi (JP); Tsutomu TETSUKA, Kasumigaura-shi (JP)

(73) Assignee: HITACHI HIGH-TECHNOLOGIES CORPORATION, Tokyo (JP)

(21) Appl. No.: 13/743,748

(22) Filed: Jan. 17, 2013

(30) Foreign Application Priority Data
May 11, 2012 (JP) 2012-109063
Sep. 24, 2012 (JP) 2012-209582

(51) Int. Cl. H01L 21/3065

(52) U.S. Cl. CPC H01L 21/3065
USPC 156/345.48

(57) ABSTRACT

A plasma processing apparatus includes a processing chamber, a flat-plate-like dielectric window, an induction coil, a flat electrode, a RF power source, a gas supply unit, and a sample stage on which a sample is mounted. A process gas supply plate is provided opposite the dielectric window on an inner side of the processing chamber, and a recess portion is formed in the flat electrode on a side opposite the induction coil corresponding to a gas supply position of the process gas supply plate.

### CLAIM OF PRIORITY

This application is based upon and claims the benefit of priority from the prior Japanese Patent Application No. 2012-109063 filed on May 11, 2012 and Application No. 2012-209582 field on Sep. 24, 2012, the entire contents of which are incorporated herein by reference.

### BACKGROUND OF THE INVENTION

1. Field of the Invention

The present invention relates to a plasma processing apparatus. More particularly, the present invention relates to an inductively coupled plasma processing apparatus.

2. Description of Related Art

In the field of manufacturing semiconductor devices, the inductively coupled plasma apparatus has been employed as the method of etching and surface treatment, which applies a radio-frequency current to an induction antenna provided outside a plasma processing chamber for processing the process gas inserted into the processing chamber to generate plasma. Various process steps use multiple gases (for example, Ar, O₂, Cl₂) depending on the film of the sample so as to perform uniform plasma processing.

Generally, Japanese Patent Application Laid-Open Publication No. 2004-235545 discloses the plasma processing apparatus as the inductively coupled plasma processing apparatus. As Japanese Patent Application Laid-Open Publication No. 2004-235545 discloses, the apparatus includes a processing chamber and a dielectric vacuum vessel, which constitutes an upper part of the processing chamber. An induction antenna is provided above the bell jar for producing plasma. A faraday shield is provided between the induction antenna and the bell jar. Application of high voltage to the faraday shield draws ions in the plasma to the bell jar side so as to clean depositions adhered onto an inner surface of the bell jar. For a gas supply method, a gas supply unit provided outside the processing chamber is used to introduce the process gas so as to be supplied into the processing chamber through a gas outlet hole formed concentrically in the side surface of the processing chamber. The supplied process gas is processed to generate the plasma in the induced magnetic field generated from the induction antenna, and is radiated to the sample on the sample stage provided inside the processing chamber. The process gas which has been subjected to plasma processing is discharged outside the processing chamber by the exhaust system provided at the lower part of the processing chamber. The plasma processing apparatus disclosed in Japanese Patent Application Laid-Open Publication No. 2004-235545 allows the aforementioned mechanism to perform the uniform plasma processing.

Japanese Patent Application Laid-Open Publication No. 2008-130651 discloses the inductively coupled plasma processing apparatus, aiming at preventing reaction products from being non-uniformly adhered onto the inner surface of the pressure-resistant dielectric member and from being cut in a uniform and well-balanced manner without structurally complicating the apparatus and impairing uniformity of the plasma above the object. The apparatus includes a first electrode that generates plasma processing from reaction gas in the chamber that can be decompressed via the pressure-resistant dielectric member, which is allowed to act on the object on the counter electrode for plasma processing such as etching, and a second electrode interposed between the first electrode and the pressure-resistant dielectric member for preventing adhesion of the reaction product onto the inner surface of the pressure-resistant dielectric member. It is well known that the apparatus is configured to set the electrode distance from the inner surface of the pressure-resistant dielectric member of the second electrode in accordance with the local difference with respect to the degree of adhesion of the reaction product on the inner surface of the dielectric member and the cut amount of the pressure-resistant dielectric member in the respective opposed regions.

Japanese Patent Application Laid-Open Publication No. 2004-356587 discloses the plasma processing apparatus with respect to the gas supply method for the capacitively coupled plasma processing apparatus. As disclosed in Japanese Patent Application Laid-Open Publication No. 2004-356587, the process gas is supplied from the center of the upper part of the processing chamber, and passes inside the patch antenna provided in the processing chamber, and is supplied from the opening formed in the lower part of the patch antenna into the processing chamber. In this way, the process gas supplied from the center of the processing chamber increases concentration of the gas above the sample. This makes it possible to improve the etching rate.

Japanese Patent Application Laid-Open Publication No. 2011-187902 discloses the plasma processing apparatus, with respect to the gas supply method for the inductively coupled plasma processing apparatus. As disclosed in Japanese Patent Application Laid-Open Publication No. 2011-187902, the dielectric vacuum window formed of the parallel circular plate is provided at the upper part of the processing chamber. The dielectric or the conductive gas flow passage is radially provided inside the vacuum window so as to supply the process gas. The process gas passes through the gas flow passage, and reaches the center of the vacuum window so as to be supplied into the processing chamber via shower holes formed in the center of the vacuum window. Like Japanese Patent Application Laid-Open Publication No. 2004-356587, the apparatus allows increase in the concentration of gas above the substrate to be processed, and improving the etching rate by supplying the process gas from the center of the processing chamber. Furthermore, the gas flow passage width is set to the dimension equal to or smaller than the mean free path of the process gas, and the gas flow passage is radially arranged. This makes it possible to prevent abnormal discharge inside the gas flow passage.

### SUMMARY OF THE INVENTION

Recently, the semiconductor device manufacturing field demands the plasma processing apparatus to provide uniformity and mass production stability of plasma generated upon processing of the sample in association with increased diameter and sophistication of the sample such as a wafer and a display. Especially, with increase in the sample diameter, the generated plasma is needed to increase the diameter correspondingly. This requires generation of the plasma with further uniformity and high density. For the uniform sample processing, it is essential to supply the process gas while being controlled to the sample surface. This is because dissociation and ionization of the supplied process gas determines spatial distribution of the plasma distribution, and the process gas is excited in the plasma to become reactive radical, which may directly influence distribution of the plasma processing characteristic. Furthermore, the flow distribution of the process gas influences conveyance of the reactive radical to be processed, and emission of the reactive product that hinders the processing.

The state of capacitive coupling between the faraday shield serving as the cleaning electrode and the plasma is changed in plane of the top plate of the processing chamber depending on the position at which the process gas is supplied. This may cause the problem that the amount of the reactive product adhered to the top plate is changed in the plane, and accordingly, uniform cleaning function cannot be obtained.

The inductively coupled plasma processing apparatus disclosed in Japanese Patent Application Laid-Open Publication No. 2004-235545 is configured to supply the process gas for producing plasma through a gas hole formed in the side surface of the processing chamber. However, as the gas hole is formed at the outer side of the sample, most of the process gas is directly discharged. For this, concentration of the gas above the sample becomes lean relative to the amount of the supplied process gas. This may cause the problem of deterioration in the etching rate and etching performance such as uniformity when coping with the diameter increase. There has been no consideration of the relationship between the process gas supply position and the capacitively coupled state.

The capacitively coupled plasma processing apparatus disclosed in Japanese Patent Application Laid-Open Publication No. 2008-130651 is configured with no consideration of the relationship between the process gas supply position and the capacitively coupled state like the Japanese Patent Application Laid-Open Publication No. 2004-235545. That is, there is no consideration of the influence of the gas supply position set in the top plate portion at the upper part of the processing chamber to which the electromagnetic field from the antenna is supplied, and the state of the capacitive coupling between the faraday shield as the cleaning electrode and the plasma to the adhesion of the reaction product to the top plate.

The capacitively coupled plasma processing apparatus disclosed in Japanese Patent Application Laid-Open Publication No. 2004-356587 is configured to supply the process gas from the center of the processing chamber so as to allow improvement in the etching performance. However, if a gas retention part is formed in the electric field such as the inner part of the patch antenna, abnormal discharge may occur in the middle of the gas supply passage. Furthermore, the relationship between the process gas supply position and the electric field distribution is not considered.

The inductively coupled plasma processing apparatus disclosed in Japanese Patent Application Laid-Open Publication No. 2011-187902 is configured to have the gas flow passage formed of the dielectric body or conductor, and width of the gas flow passage set to be equal to or smaller than the mean free path of the process gas so as to allow suppression of the abnormal discharge in the gas flow passage. However, the gas flow passage is formed as a groove by directly processing the Al₂O₃ vacuum window of the dielectric body. The groove is processed to have a size equal to 1 mm or smaller. Therefore, it is not so easy to perform the processing with high accuracy. As the resultant processing cost becomes considerably high, the method is not realistic for the apparatus intended to be mass-produced.

The technology of suppressing the abnormal discharge in the gas flow passage as disclosed in Japanese Patent Application Laid-Open Publication No. 2011-187902 by itself cannot reduce sufficient amount of the electric field in the gas flow passage, which may result in the abnormal discharge. The relationship between the process gas supply position and the capacitive coupling is not considered.

It is an object of the present invention to provide a plasma processing apparatus which allows optimization of distribution of sheath voltage generated in plane of the wall of the processing chamber, and suppression of generation of foreign matters or adhesion of the reaction products even in the structure having a process gas inlet in the electrode arrangement range that allows cleaning on the inner wall surface of the processing chamber.

It is another object of the present invention to provide a plasma processing apparatus that allows uniform generation of plasma above the sample, and high etching performance and mass production stability while preventing the abnormal discharge in spite of high intensity of the electromagnetic field of the inductively coupled plasma processing apparatus.

The present invention provides a plasma processing apparatus which includes a processing chamber for applying plasma processing to a sample, a flat-plate-like dielectric window that vacuum seals a top part of the processing chamber, an induction coil arranged above the dielectric window, a flat plate electrode arranged between the dielectric window and the induction coil, a RF power source for supplying radio-frequency power to both the induction coil and the flat plate electrode, or a plurality of RF power sources for supplying radio-frequency power to the induction coil and the flat plate electrode, individually, a gas supply unit for supplying gas into the processing chamber, and a sample stage provided in the processing chamber, on which the sample is mounted. A process gas supply plate is provided to have a predetermined gap from the dielectric window on an inner side of the processing chamber. A recess part is formed in the flat plate electrode on an opposite side of the induction coil (side of the dielectric window) corresponding to a gas supply position of the process gas supply plate.

The present invention provides a plasma processing apparatus which includes a processing chamber for applying plasma processing to a sample, a dielectric vacuum window that vacuum seals a top part of the processing chamber, an induction coil arranged above the vacuum window, a faraday shield arranged between the vacuum window and the induction coil, a RF power source for supplying radio-frequency power to both the induction coil and the faraday shield, a gas supply unit for supplying gas into the processing chamber, and a sample stage provided in the processing chamber, on which the sample is mounted. A mechanism with a function for adjusting capacitively coupled components between the faraday shield and the plasma is provided in a center part of the faraday shield.

In the above-described structure, the faraday shield may be provided with a notch having the same configuration as that of the gas inlet or the gas flow passage.

In the above-described structure, an air layer or a dielectric body with permittivity different from that of the vacuum window may be inserted into the notch of the faraday shield so as to be used.

According to the present invention, the structure in which the process gas inlet is provided in the electrode arrangement range that enables the cleaning on the inner wall surface of the processing chamber is capable of optimizing the sheath voltage distribution generated in the plane of the processing chamber wall, suppressing generation of foreign substance or adhesion of the reaction products.

According to the present invention, the notch configured corresponding to that of the center part of the faraday shield, or the gas inlet and the gas flow passage allows uniform plasma processing over an entire surface of the sample, and high etching performance and the mass production stability without causing the abnormal discharge in the case of high electromagnetic intensity of the inductively coupled plasma type.

### BRIEF DESCRIPTION OF THE DRAWINGS

FIG. 1 schematically shows a section of a structure of a plasma processing apparatus according to a first embodiment of the present invention;

FIG. 2 graphically shows an effective voltage directly below a dielectric vacuum window on which a generally employed faraday shield is provided;

FIG. 3 graphically shows an effective voltage directly below a gas release plate on which a faraday shield of the apparatus shown in FIG. 1 is provided;

FIG. 4 schematically shows a section of the structure of the plasma processing apparatus according to a second embodiment of the present invention;

FIG. 5 is a detailed view showing a peripheral part of the faraday shield of the apparatus shown in FIG. 4;

FIG. 6 graphically shows an effective voltage directly below a dielectric vacuum window on which a generally employed faraday shield is provided;

FIG. 7 graphically shows an effective voltage directly below the gas release plate on which a faraday shield of the apparatus shown in FIG. 4 is provided;

FIGS. 8A and 8B show analytical results of the faraday shield electric field distribution of the apparatus shown in FIG. 4, wherein FIG. 8A represents the electric field distribution generated from the generally employed faraday shield, and FIG. 8B represents the electric field distribution generated from the faraday shield according to the present invention;

FIG. 9 is a detailed view showing a peripheral part of the faraday shield according to a third embodiment of the present invention as another embodiment of the faraday shield shown in FIG. 5;

FIG. 10 is a detailed view showing a peripheral part of the faraday shield according to a fourth embodiment of the present invention as another embodiment of the faraday shield shown in FIG. 5;

FIG. 11 schematically shows a section of a structure of a plasma processing apparatus according to a fifth embodiment of the present invention;

FIG. 12 graphically shows an effective voltage directly below the gas release plate on which a faraday shield of the apparatus shown in FIG. 11 is provided;

FIG. 13 schematically shows a section of a structure of a plasma processing apparatus according to a sixth embodiment of the present invention; and

FIG. 14 graphically shows an effective voltage directly below a gas release plate on which the faraday shield of the apparatus shown in FIG. 13 is provided.

### MODE FOR CARRYING OUT THE INVENTION

The respective embodiments of the present invention will be described referring to the drawings.

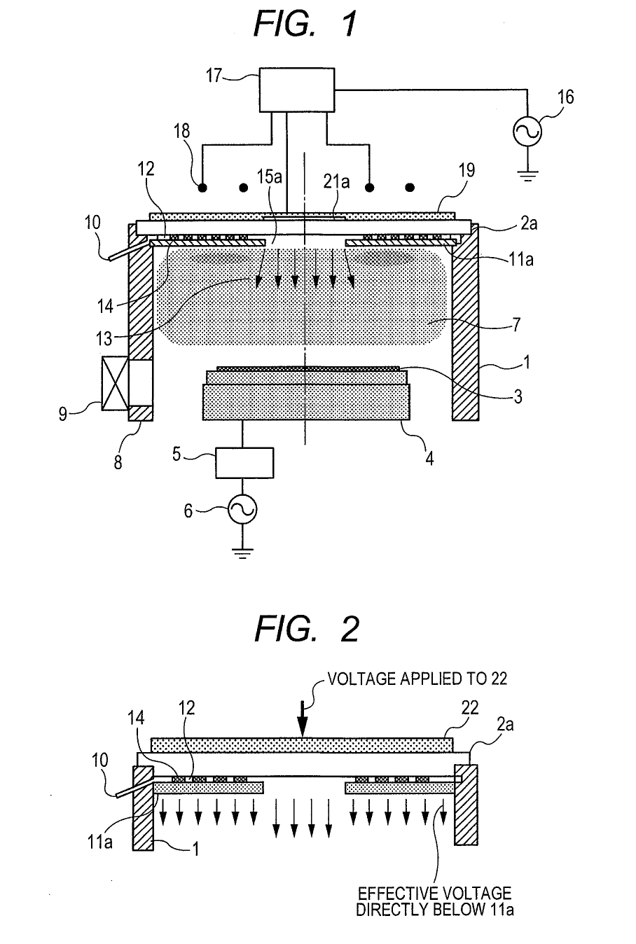

A plasma processing apparatus according to the first embodiment of the present invention will be described referring to FIGS. 1 to 3.

FIG. 1 is a schematic view of the plasma processing apparatus according to the embodiment. The plasma processing chamber includes a chamber 1 having a side wall formed by depositing ceramic to an aluminum base material, and a dielectric vacuum window 2a formed as a quartz dielectric window disposed at the upper part. A sample stage 4 is placed at the lower part of the processing chamber, on which a sample 3 such as a substrate is mounted. High frequency equal to or lower than several tens MHz from a radio-frequency (RF) power source 6 is applied to the sample 3 via a matching box 5 so as to control the ion energy from plasma 7 applied to the sample 3. In this embodiment, a wafer with diameter of 300 mm for the semiconductor device is used as the sample 3, and the power source at frequency of 800 kHz is used as the RF power source 6. An exhaust outlet 8 is formed in the chamber 1. An exhaust unit 9 located at the end of the exhaust outlet 8 serves to control the pressure in the processing chamber to the set value in the range from 0.1 Pa to several tens Pa.

The gas supplied for the plasma processing is introduced from a gas supply pipe 10 attached to the chamber 1 of the processing chamber, and flows through a gas flow passage 12 between the dielectric vacuum window 2a and a quartz gas release plate 11a so that a process gas 13 is released from above the sample 3. In this case, the gas flow passage 12 is configured by gaps among a plurality of high dielectric bodies 14 each with high permittivity, which are island-like arranged between the dielectric vacuum window 2a and the quartz gas release plate 11a. The process gas 13 is released from a circular opening 15a formed in a center of the gas release plate 11a.

An electromagnetic field for generating the plasma 7 is radiated into the processing chamber by applying output of a RF power source 16 at frequency of 13.56 MHz to a coil type radio-frequency antenna 18 via a matching box 17. If the output of the RF power source 16 is in the order of several kW, the high-frequency current becomes several tens A with the inductance of the radio-frequency antenna 18 of several μH, and accordingly, the voltage across terminals becomes several kV. A faraday shield 19 is provided between the radio-frequency antenna 18 and the plasma 7 in order to prevent direct application of high voltage of the radio-frequency antenna 18 to the plasma 7. The faraday shield 19 is capable of adjusting the RF power applied by the matching box 17 coupled to the RF power source 16. A plurality of RF power sources may be provided in order to supply radio-frequency power to the radio-frequency antenna (induction coil) and the faraday shield (plate electrode) individually. Preferably, the plane of the faraday shield is formed into a parallel plate or a circular plate in consideration of the electric field distribution.

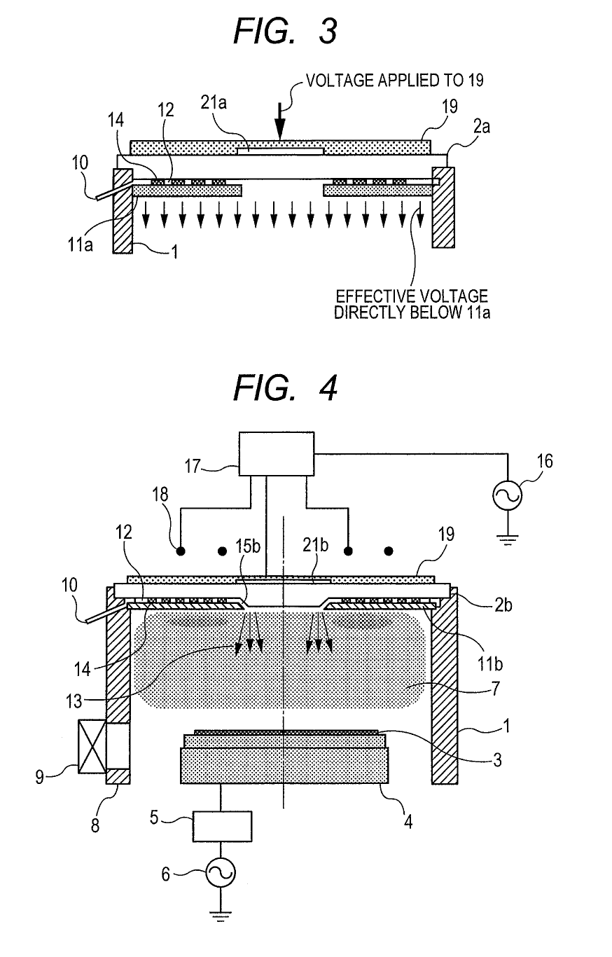

Function of the faraday shield 19 of the embodiment will be described referring to FIGS. 2 and 3.

FIG. 2 graphically shows an effective voltage distribution of a generally employed faraday shield 22, which is generated directly below the gas release plate 11a. The plasma processing apparatus according to the embodiment is provided with a plurality of high dielectric bodies 14 each formed of a material with high permittivity between the dielectric vacuum window 2a and the gas release plate 11a in order to prevent abnormal discharge in the gas flow passage 12. The electric field generated by the generally employed faraday shield 22 is absorbed by the high dielectric bodies 14, which deteriorate the effective voltage value directly below the high dielectric bodies 14.

In other words, the effective voltage distribution generated directly below the gas release plate 11a becomes non-uniform as shown by arrows in the drawing. Accordingly, it is highly possible that the plasma generated above the sample 3 becomes non-uniform.

FIG. 3 graphically shows an effective voltage distribution of the faraday shield 19 according to the embodiment, which is generated directly below the gas release plate 11a. Like FIG. 2, as the electric field is absorbed by the high dielectric bodies 14, the effective voltage value directly below the high dielectric bodies 14 is lowered. However, a notch 21a formed in the center part of the faraday shield 19 serves to weaken the electric field directly below the notch. This lowers the effective voltage value generated directly below the notch surface. Finally the effective voltage distribution generated directly below the gas release plate 11a establishes uniform distribution as shown by arrows in the drawing.

The plasma sheath voltage between the plasma, and the lower surface of the gas release plate 11a and the lower surface of the center of the dielectric vacuum window 2a corresponding to the center opening of the gas release plate 11a becomes substantially uniform. Even if a process gas inlet is formed on an electrode that causes cleaning function on the inner wall surface of the processing chamber, that is, the range where the faraday shield 19 is arranged in this case, the sheath voltage distribution generated below the lower surface of the center of the dielectric vacuum window 2a corresponding to the center opening of the gas release plate 11a may be optimized, and generation of the foreign substance or adhesion of the reaction product may be suppressed.

### Second Embodiment

A plasma processing apparatus according to a second embodiment of the present invention will be described referring to FIGS. 4 to 10. Referring to FIG. 4, the same reference numerals as those shown in FIG. 1 denote the same members, and redundant explanations will be omitted. This drawing is different from FIG. 1 in that the lower surface of the center of the dielectric vacuum window 2b has a convex shape which is fitted with the center opening of the gas release plate 11b so as to leave a predetermined gap to form a slit 15b as a gas outlet. A reference numeral 21b denotes a notch.

The process gas 13 is released from the slit 15b in the circumference direction formed between a circular trapezoidal protrusion formed on the center part of the dielectric vacuum window 2b and the circular opening in the center part of the gas release plate 11b.

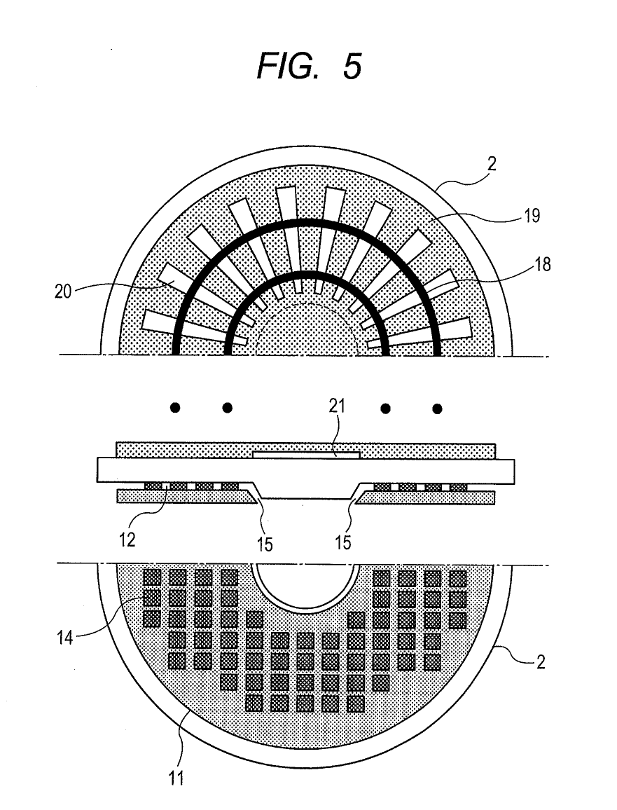

FIG. 5 is a detailed view showing a peripheral part of the faraday shield 19 of the plasma processing apparatus according to the second embodiment.

The radio-frequency antenna 18, the faraday shield 19, the dielectric vacuum window 2b, the high dielectric bodies 14 and the gas release plate 11b which are shown in FIG. 4 are arranged as illustrated in FIG. 5. Referring to FIG. 5, a reference numeral 2 denotes the dielectric vacuum window, a reference numeral 11 denotes the gas release plate, a reference numeral 15 denotes the slit, and a reference numeral 21 denotes the notch. The faraday shield 19 is provided with partially penetrating radial slits 20 over an entire surface. The notch (recess portion) 21 for forming the slit 15 as the release outlet through which the process gas 13 is released is formed in the center of the faraday shield 19 on the side of the processing chamber surface.

The inductively coupled plasma generates the plasma by permeation of the induction magnetic field generated from the radio-frequency antenna 18 into the processing chamber as described above. The faraday shield has the opening such as the slit 20, which allows permeation of the induction magnetic field. In the embodiment, the notch 21 is formed in the center of the faraday shield 19 in addition to the slit 20 thereof to achieve the object of the invention.

As described above, the RF power is applied to the faraday shield 19 according to the second embodiment, and accordingly, the electric field component generated by the faraday shield 19 is permeated into the processing chamber. This clarifies that the plasma 7 according to the embodiment is substantially generated by combining the inductively coupled component from the radio-frequency antenna 18 and the capacitively coupled component from the faraday shield 19. In other words, balance between the inductively coupled component and the capacitively coupled component is essential for generating the uniform plasma 7.

For this, besides the radial slits 20, the notch 21 is further added to the faraday shield 19 according to the second embodiment so as to allow control of the electric field as the capacitively coupled component that permeates directly below the gas release plate 11b, and generation of the uniform plasma above the sample 3.

This embodiment is capable of exerting effects even if the thickness of the notch 21 is reduced limitlessly. Assuming that the thickness of the faraday shield is set to T, the notch 21 may be formed by setting its thickness dimension range from 0.1 mm indicating accuracy that allows general machining to T−0.1 mm. The optimal thickness dimension of the notch 21 according to the embodiment is determined based on the analytical result of simulation with respect to the electric field distribution.

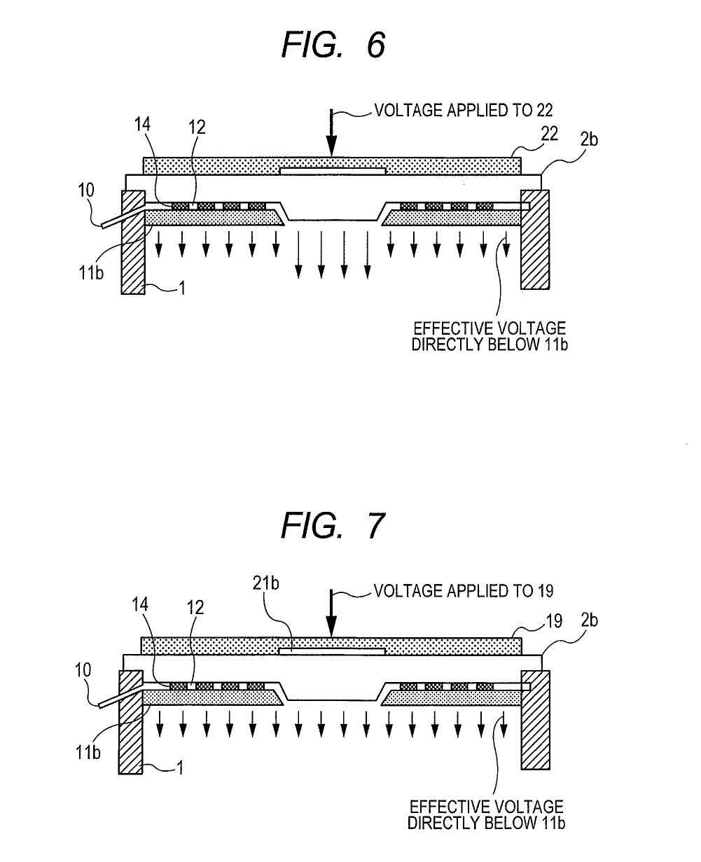

Function of the faraday shield 19 according to the embodiment will be described referring to FIGS. 6 to 8.

FIG. 6 graphically shows the effective voltage distribution of the generally employed faraday shield 22 generated directly below the gas release plate 11b. The plasma apparatus according to the embodiment includes a plurality of high dielectric bodies 14 each formed of the material with high permittivity between the dielectric vacuum window 2b and the gas release plate 11b in order to prevent abnormal discharge in the gas flow passage 12. The electric field generated by the generally employed faraday shield 22 is absorbed by the high dielectric bodies 14. As a result, the effective voltage value directly below the high dielectric bodies 14 is lowered. In other words, the effective voltage distribution generated directly below the gas release plate 11b becomes non-uniform as shown by arrows in the drawing. It is therefore likely that the plasma generated above the sample 3 becomes non-uniform. FIG. 7 graphically shows the effective voltage distribution of the faraday shield 19 according to the embodiment, which is generated directly below the gas release plate 11b. Like the view shown in FIG. 6, as the electric field is absorbed by the high dielectric bodies 14, the effective voltage value directly below the high dielectric bodies 14 is lowered. However, the electric field generated directly below the notch 21b formed in the center of the faraday shield 19 is weakened. Then the effective voltage value generated directly below the notch is lowered. Finally, the effective voltage distribution generated directly below the gas release plate 11b may be made uniform as shown by arrows in the drawing.

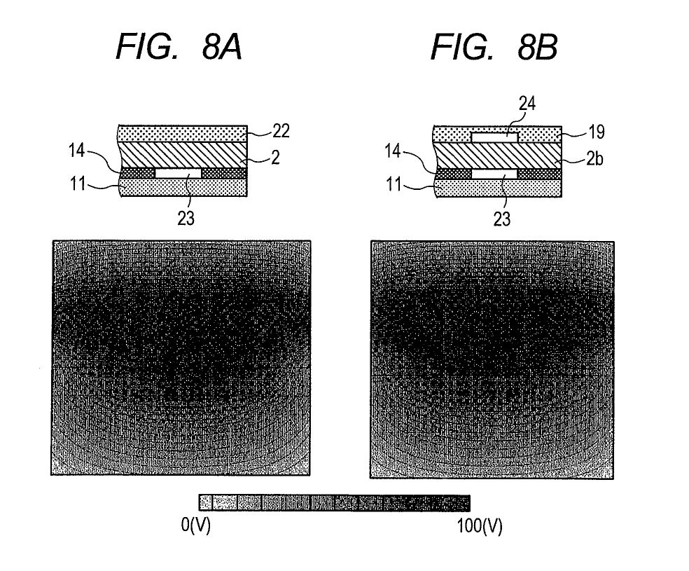

FIGS. 8A and 8B show analytical results of simulating the electric field distribution generated from the faraday shield for confirmation of the effect derived from the notch formed in the center of the faraday shield. The simulation analysis is performed with respect to Al₂O₃ (relative permittivity: 10) high dielectric body 14 with thickness of 4 mm and an air layer 23 (relative permittivity: 1) interposed between the quartz (relative permittivity: 3.5) gas release plate 11 with thickness of 10 mm and the quartz (relative permittivity: 3.5) dielectric vacuum window 2 with the thickness of 15 mm. The faraday shield with thickness of 6 mm is provided on the dielectric vacuum window 2, and the electric field distribution upon application of voltage (100 V) to the upper surface of the faraday shield is output. FIGS. 8A and 8B show the electric field distributions obtained when the notch with thickness of 4 mm is formed in the lower surface of the faraday shield directly above the air layer, and the one without forming the notch for the comparison purpose.

FIG. 8A shows the electric field distribution when the generally employed faraday shield 22 is provided. FIG. 8B shows the electric field distribution when the faraday shield 19 according to the embodiment is provided. As shown in the drawing, compared to the generally employed faraday shield 22, the faraday shield 19 according to the embodiment has the notch which reduces the electric field distribution directly below the notch. Specifically, the notch serves to generate another air layer 24 in the part of the lower surface of the faraday shield, and the resistance corresponding to the air layer 24 is generated. This reduces the electric field directly below the air layer 24, and the capacitively coupled component is reduced. The embodiment is capable of making the total electric field that is permeated into the dielectric vacuum window 2b appropriate by adjusting the dimension of the notch 21. This makes it possible to generate the plasma with uniformity above the sample 3. In the embodiment, the height of the gas flow passage 12 is made equal to the width of the notch 21b in the lower surface of the faraday shield 19 in accordance with the simulation analytical results so as to ensure generation of uniform plasma above the sample 3.

### Third Embodiment

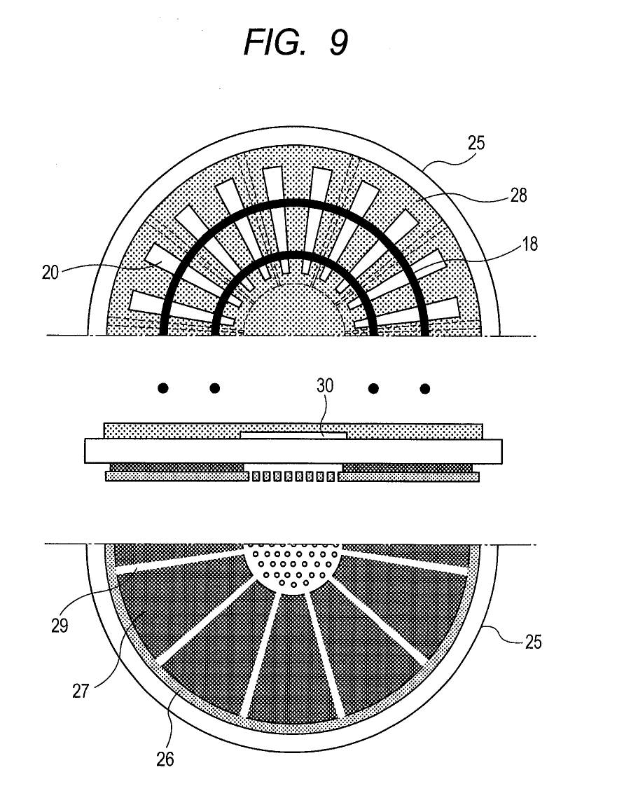

A third embodiment of the present invention will be described referring to FIG. 9. FIG. 9 is a detailed view of another embodiment of a peripheral part of the faraday shield of the plasma processing apparatus according to the second embodiment. Referring to FIG. 9, the same reference numerals as those described in the embodiment denote the same members, and redundant explanations will be omitted. This embodiment is different from the one shown in FIG. 5 in that the method of supplying gas to the dielectric vacuum window 2 and the gas release plate 11 is different from the method of supplying gas to the high dielectric bodies 14. A faraday shield 28 has a gas flow passage configuration that is the same as the gas flow passage 29 formed in a high dielectric body 27, in other words, the configuration which includes a plurality of flow passages radially connected to the outer peripheral part from the center opening hole in this case. A notch 30 with the same configuration as the gas flow passage 29 is formed. The notch 30 allows reduction in the electric field in the gas flow passage 29. A reference numeral 25 denotes the dielectric vacuum window, and a reference numeral 26 denotes the gas release plate. The inductively coupled plasma processing apparatus shown in FIG. 4 is operated using the gas supply method and the faraday shield 28 shown in FIG. 9 for machining of the semiconductor substrate. The resultant plasma processing may be performed with excellent uniformity, which further ensures suppression of the abnormal discharge in the gas flow passage.

The embodiment provides the similar advantages as those obtained in the aforementioned embodiment. By making the gas flow passage configuration the same as the notch configuration, the abnormal discharge in the gas flow passage may be suppressed.

### Fourth Embodiment

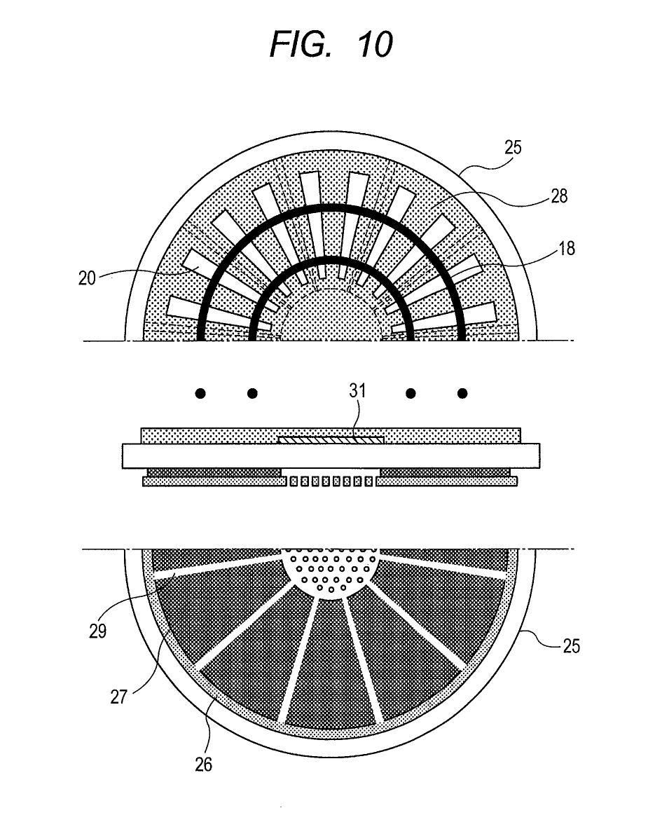

A fourth embodiment of the present invention will be described referring to FIG. 10.

FIG. 10 is a detailed view of another embodiment of a peripheral part of the faraday shield of the plasma processing apparatus according to the second embodiment. The reference numerals shown in FIG. 9 which are the same as those described in the aforementioned embodiment denote the same members, and redundant explanations will be omitted. This embodiment is different from the one shown in FIG. 9 in that a low dielectric body 31 with permittivity lower than that of the dielectric vacuum window 25 and the gas release plate 26 (for example, polytetrafluoroethylene) is provided instead of the air layer of the notch 30 formed in the faraday shield 28. The semiconductor substrate is machined using the inductively coupled plasma processing apparatus shown in FIG. 4, which is provided with the low dielectric body 31 with low permittivity as shown in FIG. 10. This makes it possible to perform plasma processing with excellent uniformity, and suppress abnormal discharge in the gas flow passage.

As described above, the embodiment may provide the similar effects to those derived from the aforementioned embodiment.

### Fifth Embodiment

For the first to the fourth embodiments, the mechanism for supplying the process gas 13 from the center of the gas supply plate, that is, the center of the plasma processing chamber so that concentration of the gas above the sample 3 becomes high. This may increase the plasma density above the sample, thus increasing the etching rate. However, the plasma distribution above the sample is of great variety depending on type and nature of the process gas, and condition of the etching process. There may be the case that the uniformity of the etching rate is impaired by configuration of the distribution. It is therefore essential to align the process gas supply position with the position optimal for the processing in order to achieve the object of uniform and stable etching process.

In view of the aforementioned problem, the example that allows gas to be supplied to the position optimal for the processing will be described as the embodiment to achieve the object.

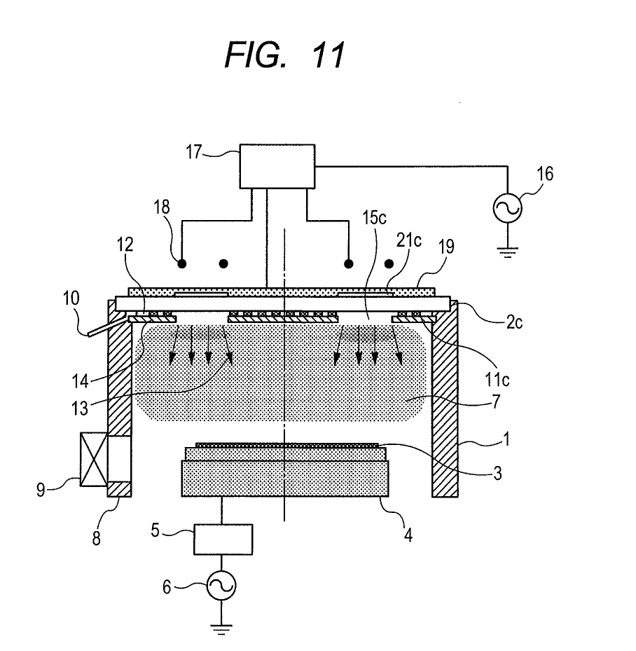

A plasma processing apparatus according to a fifth embodiment of the present invention will be described referring to FIG. 11. Description that has been already explained in any one of the first to fourth embodiments but is not described in this embodiment may apply thereto unless otherwise specified.

The same reference numerals in FIG. 11 as those shown in FIG. 1 denote the same members, and redundant explanations will be omitted. FIG. 11 is different from FIG. 1 in that a ring opening is formed in the gas release plate 11c, which serves as the gas release outlet (inlet) 15c, and a notch 21c corresponding to the gas inlet configuration is formed in the faraday shield 19. Additionally, the ring opening in the gas release plate 11c and the notch 21c of the faraday shield 19 are located on an intermediate diameter of the gas release plate 11c (intermediate position between the center and the outer periphery of the gas release plate). The reference numeral 2c denotes the dielectric vacuum window. The process gas 13 passes through the gas flow passage 12 between the dielectric vacuum window 2c and the gas release plate 11c, and is released from the circular opening 15c formed in the intermediate portion (intermediate region between the center and the outer periphery) of the gas release plate 11c into the chamber.

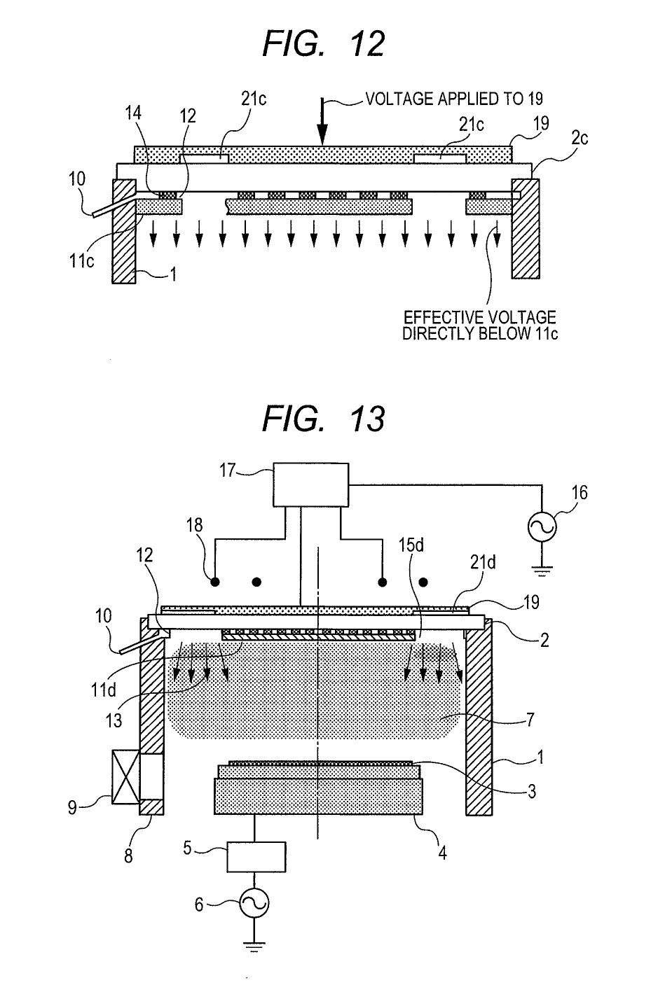

FIG. 12 graphically shows the effective voltage distribution of the faraday shield 19 according to the embodiment, which is generated directly below the gas release plate 11. Like the aforementioned embodiment, this embodiment includes a plurality of high dielectric bodies 14 between the gas release plate 11c and the dielectric vacuum window 2c. The generally employed faraday shield makes the effective voltage non-uniform as shown in FIG. 6. Use of the faraday shield 19 according to the embodiment is capable of providing the uniform effective voltage distribution as shown by arrows in the drawing.

As described above, this embodiment is capable of providing the similar effects to those derived from the aforementioned embodiment. The diameter of the ring opening is arbitrarily set to align the process gas supply position with the position optimal for the processing, resulting in uniform process.

### Sixth Embodiment

A plasma processing apparatus according to a sixth embodiment of the present invention will be described referring to FIG. 13. Description that has already been explained in any one of the first to fifth embodiments, which is not described in this embodiment may apply thereto unless otherwise specified.

Referring to FIG. 13, the same reference numerals as those shown in FIG. 1 denote the same members, and redundant explanations will be omitted. FIG. 13 is different from FIG. 1 in that a ring opening formed in the gas release plate 15d serves as the gas release outlet (inlet), and a notch 21d corresponding to the configuration of the gas inlet is formed in the faraday shield 19. Additionally, the ring opening of the gas release plate 11d and the notch 21d of the faraday shield 19 are positioned at the outer periphery of the gas release plate 11d, respectively. The process gas 13 passes through the gas flow passage 12 between the dielectric vacuum window 2 and the gas release plate 11d, and is released from the circular opening formed in the outer periphery of the gas release plate 11d into the chamber.

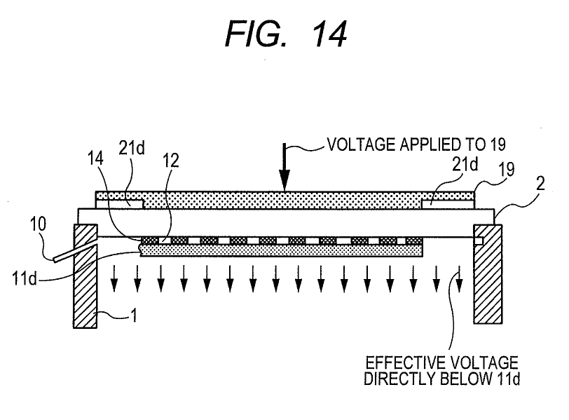

FIG. 14 graphically shows the effective voltage distribution of the faraday shield 19 generated directly below the gas release plate 11d according to the embodiment. Like the aforementioned embodiment, this embodiment includes a plurality of high dielectric bodies 14 between the gas release plate lid and the dielectric vacuum window 2. The generally employed faraday shield makes the effective voltage non-uniform as shown in FIG. 6. The faraday shield 19 according to the embodiment provides the uniform effective voltage distribution as shown by arrows in the drawing.

This embodiment is capable of providing the similar effects to those obtained by the aforementioned embodiment. The diameter of the ring opening is arbitrarily set to align the process gas supply position with the position optimal for the processing so as to achieve uniform processing.

The diameter of the ring opening is arbitrarily set if necessary so as to be formed on the outer periphery rather than the mid position in the plane.

The embodiment provides the similar effects to those of the aforementioned embodiment. The diameter of the ring opening is arbitrarily set to align the process gas supply position to the position optimal for the processing so as to achieve the uniform processing.

The present invention is not limited to these embodiments, and may include various modified examples. For example, the aforementioned embodiments have been described in detail for the purpose of clear understanding of the present invention. It is therefore not limited to the case where all the structures that have been explained are provided. A part of the structure according to any one of the embodiments may be replaced with the structure according to another embodiment. The structure of any one of the embodiments may be added to the structure of another embodiment. Alternatively, each of the embodiments may be partially added to, deleted from and replaced with another embodiment. More specifically, it may be configured by forming the circular notch in the center, the ring notch in the region from the center to the intermediate position of the outer periphery, and the ring notch in the outer periphery simultaneously. It may also be configured by combining any of the aforementioned notches.

What is claimed is:

1. A plasma processing apparatus comprising:
a processing chamber for applying plasma processing to a sample;
a flat-plate-like dielectric window that vacuum seals a top part of the processing chamber;
an induction coil arranged above the dielectric window;
a flat plate electrode arranged between the dielectric window and the induction coil;
a RF power source for supplying radio-frequency power to both the induction coil and the flat plate electrode, or a plurality of RF power sources for supplying radio-frequency power to the induction coil and the flat plate electrode, individually;
a gas supply unit for supplying gas into the processing chamber; and
a sample stage provided in the processing chamber, on which the sample is mounted,
wherein a process gas supply plate is provided to have a predetermined gap from the dielectric window on an inner side of the processing chamber; and
a recess part is formed in the flat plate electrode on a side of the dielectric window corresponding to a gas supply position of the process gas supply plate.

2. A plasma processing apparatus comprising:
a processing chamber for applying plasma processing to an sample;
a dielectric vacuum window that vacuum seals a top part of the processing chamber;
an induction coil arranged above the vacuum window;
a faraday shield arranged between the vacuum window and the induction coil;
a RF power source for supplying radio-frequency power to both the induction coil and the faraday shield;
a gas supply unit for supplying gas into the processing chamber; and
a sample stage provided in the processing chamber, on which the sample is mounted,
wherein a mechanism with a function for adjusting capacitively coupled components between the faraday shield and the plasma is provided in a center part of the faraday shield.

3. The plasma processing apparatus according to claim 2,
wherein the faraday shield has a parallel plate shape or a circular plate shape; and
a notch is formed in a center part of the faraday shield for adjusting the capacitively coupled components between the faraday shield and the plasma.

4. The plasma processing apparatus according to claim 2, wherein the notch allows an air layer or a dielectric body different from the vacuum window to be provided between the faraday shield and the plasma.

5. The plasma processing apparatus according to claim 2, wherein the notch has a configuration which is the same as that of a gas inlet of the gas supply unit or a gas flow passage.

6. The plasma processing apparatus according to claim 2, wherein when a thickness of the notch is set to T, the notch is formed to have the thickness equal to or larger than 0.1 mm, and equal to or smaller than T−0.1 mm.

7. The plasma processing apparatus according to claim 5, wherein the notch has a circular plane configuration.

8. The plasma processing apparatus according to claim 5, wherein the notch has a ring plane configuration.

9. The plasma processing apparatus according to claim 5, wherein a thickness of the notch has the same dimension as a height of the gas flow passage.

10. The plasma processing apparatus according to claim 2, wherein the faraday shield has partially penetrating radial slits.
